(19) United States
(12) Patent Application Publication
(10) Pub. No.: US 2026/0370205 A1
(43) Pub. Date: Nov. 19, 2026

(54) MATCHING CIRCUIT AND POWER AMPLIFICATION CIRCUIT

(71) Applicant: Murata Manufacturing Co., Ltd., Nagaokakyo-shi (JP)

(72) Inventor: Makoto ITOU, Nagaokakyo-shi (JP)

(21) Appl. No.: 19/672,947

(22) Filed: May 11, 2026

(30) Foreign Application Priority Data
May 15, 2025 (JP) 2025-082130

(51) Int. Cl. H03H 7/38; H03F 3/189; H03F 3/217

(52) U.S. Cl. CPC H03H 7/38; H03F 3/189; H03F 3/2171

(57) ABSTRACT

A matching circuit includes a first capacitor having one end connected to a first node and another end connected to a second node, a first switch having one end connected to the first node and another end connected to the second node, a first inductor having one end connected to the second node and another end connected to a third node, a second inductor having one end connected to the third node and another end connected to a fourth node, a second switch having one end connected to the fourth node and another end connected to a reference potential, and a third switch having one end connected to the third node and another end connected to the reference potential.

### REFERENCE TO RELATED APPLICATION

This application claims priority from Japanese Patent Application No. 2025-082130, filed on May 15, 2025. The content of these applications are incorporated herein by reference in its entirety.

### BACKGROUND OF THE DISCLOSURE

### 1. Field of the Disclosure

The present disclosure relates to a matching circuit and a power amplification circuit.

### 2. Description of the Related Art

A matching circuit including a transformer is described in Japanese Unexamined Patent Application Publication No. 2-261209.

### BRIEF SUMMARY OF THE DISCLOSURE

In some cases, a single power amplification circuit amplifies radio-frequency signals of a plurality of bands. In such a power amplification circuit, when the matching circuit including the transformer is used, an out of band gain (OOB gain) may be produced.

The present disclosure is made in view of the above description, and a possible benefit of the present disclosure is to enable suppression of an OOB gain.

According to an aspect of the present disclosure, a matching circuit includes a first capacitor having one end electrically connected to a first node and another end electrically connected to a second node, a first switch having one end electrically connected to the first node and another end electrically connected to the second node, a first inductor having one end electrically connected to the second node and another end electrically connected to a third node, a second inductor having one end electrically connected to the third node and another end electrically connected to a fourth node, a second switch having one end electrically connected to the fourth node and another end electrically connected to a reference potential, and a third switch having one end electrically connected to the third node and another end electrically connected to the reference potential.

According to another aspect of the present disclosure, a power amplification circuit includes the above-described matching circuit, a first amplifier having an input terminal electrically connected to the second node, an interstage matching circuit having one end electrically connected to an output terminal of the first amplifier, a fifth switch having one end electrically connected to another end of the interstage matching circuit, a sixth switch having one end electrically connected to the other end of the interstage matching circuit, a second amplifier having an input terminal electrically connected to another end of the fifth switch, and a third amplifier having an input terminal electrically connected to another end of the sixth switch.

According to the present disclosure, suppression of the OOB gain is enabled.

### BRIEF DESCRIPTION OF THE SEVERAL VIEWS OF THE DRAWINGS

FIG. 1 illustrates a configuration of a power amplification circuit according to a first embodiment;

FIG. 2 illustrates a configuration of an input matching circuit according to the first embodiment;

FIG. 3 is an equivalent circuit diagram of the input matching circuit according to the first embodiment;

FIG. 4 is an equivalent circuit diagram of the input matching circuit according to the first embodiment;

FIG. 5 illustrates a configuration of an input matching circuit according to a reference example;

FIG. 6 illustrates an example of a configuration of inductors of the input matching circuit according to the first embodiment;

FIG. 7 illustrates a circuit simulation result of an inductor of the input matching circuit according to the first embodiment;

FIG. 8 illustrates a configuration of an input matching circuit according to a comparative example;

FIG. 9 illustrates a circuit simulation result of the power amplification circuits according to the first embodiment and according to the comparative example;

FIG. 10 illustrates a configuration of an input matching circuit according to a second embodiment;

FIG. 11 is an equivalent circuit diagram of the input matching circuit according to the second embodiment; and

FIG. 12 is an equivalent circuit diagram of the input matching circuit according to the second embodiment.

### DETAILED DESCRIPTION OF THE DISCLOSURE

Hereinafter, embodiments of the present disclosure are described in detail with reference to the drawings. It should be understood that the present disclosure is not limited by the embodiments. It is needless to say that each embodiment is exemplary and configurations described in different embodiments can be partially replaced or combined. In a second embodiment and after, description of the same features as the features of the first embodiment is omitted, and only the features different from those of the first embodiment are described. In particular, a similar operation effect produced by a similar configuration is not repeatedly described on an embodiment-by-embodiment basis.

### First Embodiment

### General Overview

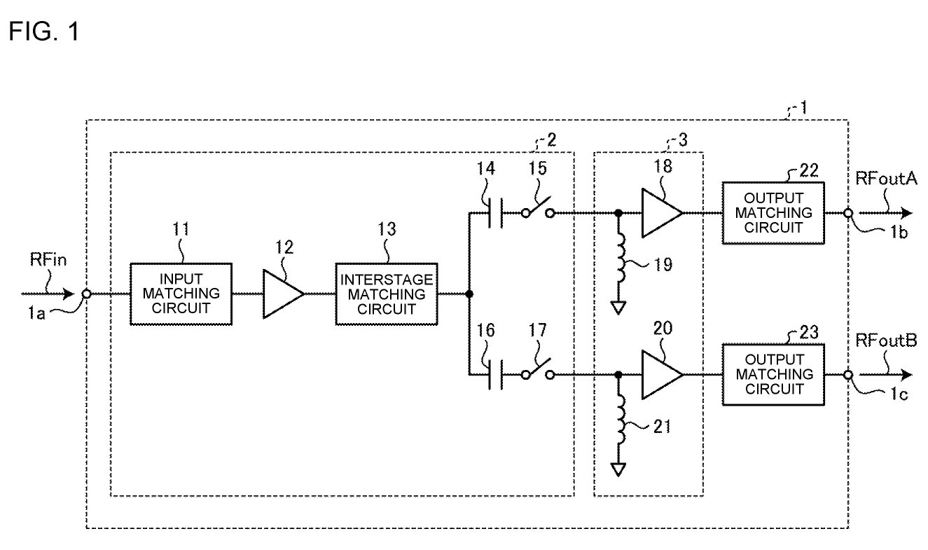

FIG. 1 illustrates a configuration of a power amplification circuit according to an embodiment. A power amplification circuit 1 can amplify a radio-frequency signal of a first band A and a radio-frequency signal of a second band B having a higher frequency than the frequency of the first band A.

Although the frequency of the first band A or the frequency of the second band B is not particularly limited, the frequency of the second band B is comparatively higher than the frequency of the first band A.

A radio-frequency signal RFin is inputted to a terminal 1a of the power amplification circuit 1. The radio-frequency signal RFin may be the radio-frequency signal of the first band A or the radio-frequency signal of the second band B. Alternatively, the radio-frequency signal RFin may be a signal in which the radio-frequency signal of the first band A and the radio-frequency signal of the second band B are superposed (mixed) on each other.

When the power amplification circuit 1 outputs a radio-frequency signal RFoutA of the first band A, the power amplification circuit 1 outputs the radio-frequency signal RFoutA not from a terminal 1c but from a terminal 1b. When the power amplification circuit 1 outputs a radio-frequency signal RFoutB of the second band B, the power amplification circuit 1 outputs the radio-frequency signal RFoutB not from the terminal 1b but from the terminal 1c.

Hereinafter, an operation mode in which the power amplification circuit 1 outputs the radio-frequency signal RFoutA of the first band A may be referred to as a "first operation mode". Also, an operation mode in which the power amplification circuit 1 outputs the radio-frequency signal RFoutB of the second band B may be referred to as a "second operation mode".

### Entire Configuration

The power amplification circuit 1 includes the following components: an input matching circuit 11, a first stage (drive stage) amplifier 12, an interstage matching circuit 13, a DC blocking capacitor 14, a switch 15, a DC blocking capacitor 16, a switch 17, a final stage (power stage) amplifier 18, a shunt inductor 19, a final stage (power stage) amplifier 20, a shunt inductor 21, an output matching circuit 22, and an output matching circuit 23.

The input matching circuit 11 corresponds to an example of a "matching circuit" of the present disclosure. The amplifier 12 corresponds to an example of a "first amplifier" of the present disclosure. The switch 15 corresponds to an example of a "fifth switch" of the present disclosure. The switch 17 corresponds to an example of a "sixth switch" of the present disclosure. The amplifier 18 corresponds to an example of a "second amplifier" of the present disclosure. The amplifier 20 corresponds to an example of a "third amplifier" of the present disclosure.

Although the input matching circuit 11, the amplifier 12, the interstage matching circuit 13, the DC blocking capacitor 14, the switch 15, the DC blocking capacitor 16, and the switch 17 are exemplified as being formed on a silicon on insulator (SOI) substrate 2, the present disclosure is not limited thereto. Although the amplifier 12 is exemplified as including a field effect transistor (FET) formed on a silicon on insulator (SOI) substrate 2 as an amplification transistor, the present disclosure is not limited thereto.

Although the amplifier 18, the shunt inductor 19, the amplifier 20, and the shunt inductor 21 are exemplified as being formed on a gallium arsenide (GaAs) substrate 3, the present disclosure is not limited thereto. Although the amplifier 18 and the amplifier 20 are each exemplified as including a bipolar transistor formed on the GaAs substrate 3 as an amplification transistor, the present disclosure is not limited thereto. Although a heterojunction bipolar transistor (HBT) is exemplified as the bipolar transistor, the present disclosure is not limited thereto.

Each transistor may be a multi-finger transistor in which a plurality of unit transistors are connected in electrically parallel. The unit transistor refers to a minimum configuration of forming a transistor.

One end of the input matching circuit 11 is electrically connected to the terminal 1a. Another end of the input matching circuit 11 is electrically connected to an input terminal of the amplifier 12. An output terminal of the amplifier 12 is electrically connected to one end of the interstage matching circuit 13.

One end of the DC blocking capacitor 14 is electrically connected to another end of the interstage matching circuit 13. Another end of the DC blocking capacitor 14 is electrically connected to one end of the switch 15.

In the first operation mode, the switch 15 is controlled by a control circuit (not illustrated) to be turned on. In the second operation mode, the switch 15 is controlled by the control circuit to be turned off.

The control circuit may be disposed inside the power amplification circuit 1 or outside the power amplification circuit 1.

One end of the shunt inductor 19 is electrically connected to another end of the switch 15. Another end of the shunt inductor 19 is electrically connected to a reference potential. Although a ground potential is exemplified as the reference potential, the present disclosure is not limited thereto.

An input terminal of the amplifier 18 is electrically connected to the other end of the switch 15. An output terminal of the amplifier 18 is electrically connected to one end of the output matching circuit 22. Another end of the output matching circuit 22 is electrically connected to the terminal 1b.

One end of the DC blocking capacitor 16 is electrically connected to the other end of the interstage matching circuit 13. Another end of the DC blocking capacitor 16 is electrically connected to one end of the switch 17.

In the first operation mode, the switch 17 is controlled by the control circuit to be turned off. In the second operation mode, the switch 17 is controlled by the control circuit to be turned on.

One end of the shunt inductor 21 is electrically connected to another end of the switch 17. Another end of the shunt inductor 21 is electrically connected to the reference potential.

An input terminal of the amplifier 20 is electrically connected to the other end of the switch 17. An output terminal of the amplifier 20 is electrically connected to one end of the output matching circuit 23. Another end of the output matching circuit 23 is electrically connected to the terminal 1c.

In the first operation mode, the power amplification circuit 1 amplifies the radio-frequency signal RFin along a path extending from the terminal 1a through the input matching circuit 11, the amplifier 12, the interstage matching circuit 13, the DC blocking capacitor 14, the switch 15, the amplifier 18, and the output matching circuit 22 to the terminal 1b, and outputs the radio-frequency signal RFoutA from the terminal 1b.

In the second operation mode, the power amplification circuit 1 amplifies the radio-frequency signal RFin along a path extending from the terminal 1a through the input matching circuit 11, the amplifier 12, the interstage matching circuit 13, the DC blocking capacitor 16, the switch 17, the amplifier 20, and the output matching circuit 23 to the terminal 1c, and outputs the radio-frequency signal RFoutB from the terminal 1c.

In the power amplification circuit 1, when distortion of the radio-frequency signal is reduced by, for example, the interstage matching circuit 13, an out of band (OOB) gain may be suppressed by the input matching circuit 11.

### Configuration of Input Matching Circuit 11

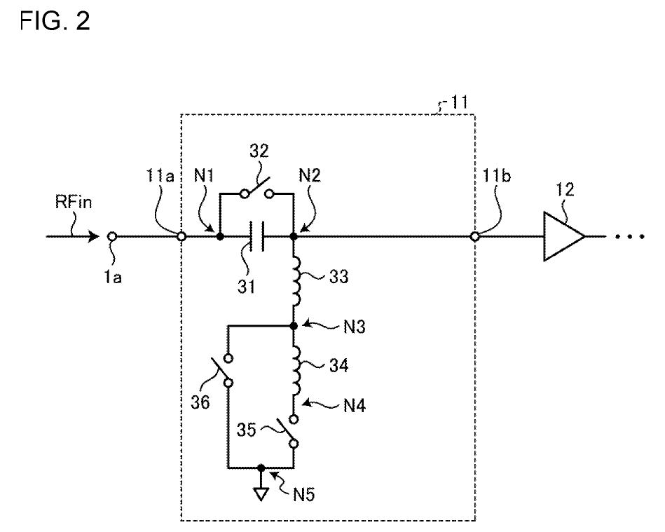

FIG. 2 illustrates a configuration of the input matching circuit according to the first embodiment. A terminal 11a of the input matching circuit 11 is electrically connected to the terminal 1a of the power amplification circuit 1. A terminal 11b of the input matching circuit 11 is electrically connected to the input terminal of the amplifier 12.

The input matching circuit 11 includes a capacitor 31, a switch 32, an inductor 33, an inductor 34, a switch 35, and a switch 36.

The capacitor 31 corresponds to an example of a "first capacitor" of the present disclosure. The switch 32 corresponds to an example of a "first switch" of the present disclosure. The inductor 33 corresponds to an example of a "first inductor" of the present disclosure. The inductor 34 corresponds to an example of a "second inductor" of the present disclosure. The switch 35 corresponds to an example of a "second switch" of the present disclosure. The switch 36 corresponds to an example of a "third switch" of the present disclosure.

One end of the capacitor 31 is electrically connected to a node N1. The node N1 is electrically connected to the terminal 11a.

The node N1 corresponds to an example of a "first node" of the present disclosure.

Another end of the capacitor 31 is electrically connected to a node N2. The node N2 is electrically connected to the terminal 11b.

The node N2 corresponds to an example of a "second node" of the present disclosure.

One end of the switch 32 is electrically connected to the node N1. Another end of the switch 32 is electrically connected to the node N2.

In the first operation mode, the switch 32 is controlled by the control circuit to be turned on. In the second operation mode, the switch 32 is controlled by the control circuit to be turned off.

One end of the inductor 33 is electrically connected to the node N2. Another end of the inductor 33 is electrically connected to a node N3.

The node N3 corresponds to an example of a "third node" of the present disclosure.

One end of the inductor 34 is electrically connected to the node N3. Another end of the inductor 34 is electrically connected to a node N4. One end of the switch 35 is electrically connected to the node N4. Another end of the switch 35 is electrically connected to a node N5. The node N5 is electrically connected to a reference potential.

The node N4 corresponds to an example of a "fourth node" of the present disclosure.

In the first operation mode, the switch 35 is controlled by the control circuit to be turned on. In the second operation mode, the switch 35 is controlled by the control circuit to be turned off.

One end of the switch 36 is electrically connected to the node N3. Another end of the switch 36 is electrically connected to the node N5.

In the first operation mode, the switch 36 is controlled by the control circuit to be turned off. In the second operation mode, the switch 36 is controlled by the control circuit to be turned on.

### Equivalent Circuit of Input Matching Circuit 11 in First Operation Mode

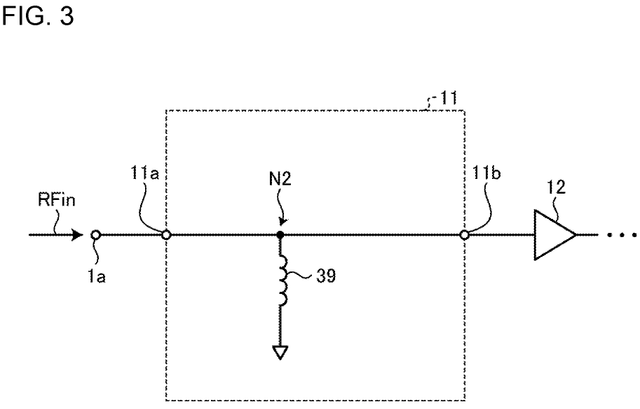

FIG. 3 is an equivalent circuit diagram of the input matching circuit according to the first embodiment. Specifically, FIG. 3 is the equivalent circuit diagram of the input matching circuit 11 in the first operation mode.

In the first operation mode, the switch 32 is controlled to be turned on, the switch 35 is controlled to be turned on, and the switch 36 is controlled to be turned off. Accordingly, the input matching circuit 11 includes an inductor 39. Here, in the inductor 39, the inductor 33 and the inductor 34 are connected in series.

### Equivalent Circuit of Input Matching Circuit 11 in Second Operation Mode

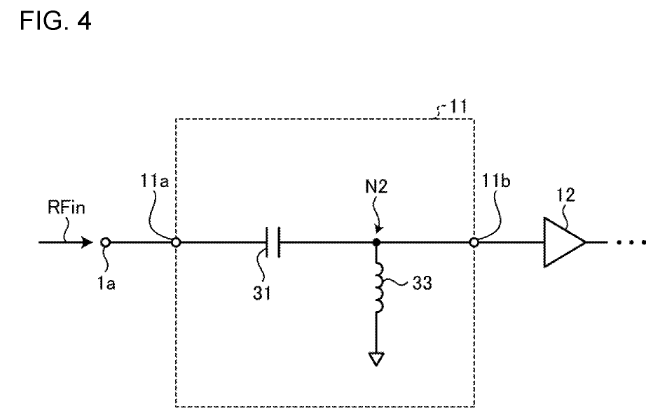

FIG. 4 is an equivalent circuit diagram of the input matching circuit according to the first embodiment. Specifically, FIG. 4 is the equivalent circuit diagram of the input matching circuit 11 in the second operation mode.

In the second operation mode, the switch 32 is controlled to be turned off, the switch 35 is controlled to be turned off, and the switch 36 is controlled to be turned on. Accordingly, the input matching circuit 11 becomes a high-pass filter including the capacitor 31 and the inductor 33 which are connected in an L shape.

### Necessity of Switch 35 of Input Matching Circuit 11

From the viewpoint of the circuit diagram of the input matching circuit 11 (see FIG. 2), it can be considered that the switch 35 may be omitted and the other end of the inductor 34 may be fixedly connected to a reference potential.

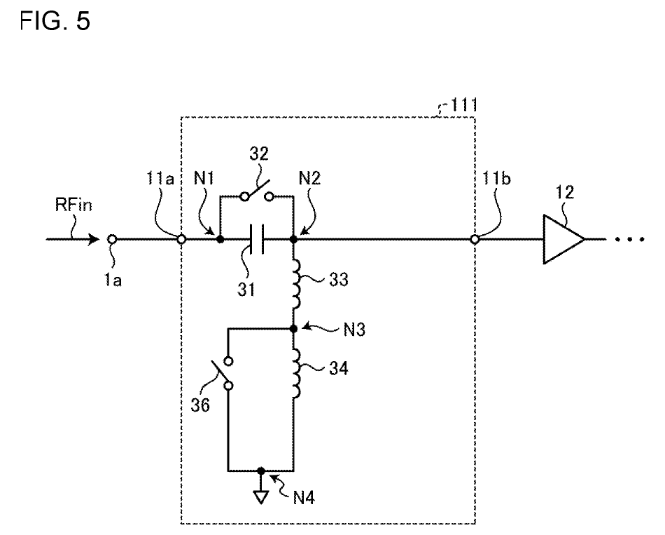

FIG. 5 illustrates a configuration of an input matching circuit according to a reference example. Compared to the input matching circuit 11 (see FIG. 2), an input matching circuit 111 according to the reference example does not include the switch 35. The other end of the inductor 34 is electrically connected to the node N4. The node N4 is connected to the reference potential in a fixed manner. The other end of the switch 36 is electrically connected to the node N4.

In the first operation mode, the switch 36 is turned off. In this case, an inductor in which the inductor 33 and the inductor 34 are connected in series is electrically connected between the node N2 and the reference potential (node N4).

In the second operation mode, the switch 36 is turned on. In this case, both the one end and the other end of the inductor 34 are at the reference potential, and accordingly, the inductor 34 may be regarded as negligible. That is, the inductor 33 is electrically connected between the node N2 and the reference potential (node N4).

As described above, from the viewpoint of the circuit diagram of the input matching circuit 11 (see FIG. 2), it seems that the switch 35 is unnecessary.

However, in the embodiment, it has been determined that the input matching circuit 11 includes the switch 35. The reason for this is as follows.

A case in which the inductor 33 and the inductor 34 are formed on a single substrate (the SOI substrate 2 in the present embodiment) is discussed. In this case, in order to reduce the substrate area of the SOI substrate 2, the inductor 33 and the inductor 34 may be formed by a single wire wound in a spiral manner.

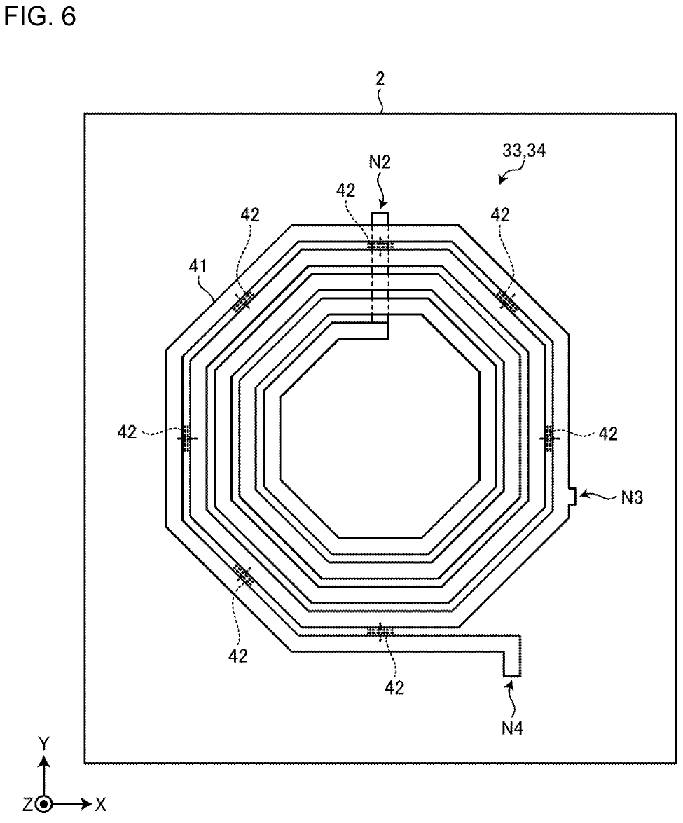

FIG. 6 illustrates an example of a configuration of the inductors of the input matching circuit according to the first embodiment.

The inductor 33 and the inductor 34 include a single wire 41 wound in a spiral manner. The wire 41 is formed on the SOI substrate 2.

The wire 41 is wound about four and a half turns counterclockwise in plan view. In plan view, the SOI substrate 2 is seen in a direction perpendicular to the SOI substrate 2.

A portion of the wire 41 from the node N2 to the node N3 corresponds to the inductor 33. A portion of the wire 41 from the node N3 to the node N4 corresponds to the inductor 34.

The following considers a case in which, as is the case with the input matching circuit 111 according to the reference example (see FIG. 5), the node N4 is fixedly connected to the reference potential.

In the second operation mode, the node N3 is electrically connected to the node N4 via the switch 36 (see FIG. 5). At this time, when the node N4 is fixedly connected to the reference potential, the outermost turn of the wire 41 (the portion from the node N3 to the node N4, corresponding to the inductor 34) is at the reference potential. Accordingly, the second outermost turn of the wire 41 (corresponding to the inductor 33) is subjected to the influence of the outermost turn of the wire 41 (reference potential) via a parasitic capacitance 42 between the outermost turn of the wire 41 (reference potential) and the second outermost turn of the wire 41. That is, the inductance value of the inductor 33 is reduced by the influence of the outermost turn of the wire 41 (reference potential).

In contrast, the following considers a case in which, as is the case with the input matching circuit 11 according to the first embodiment (see FIG. 2), the switch 35 is provided between the node N4 and the node N5.

In the second operation mode, the node N3 is electrically connected to the reference potential (node N5) via the switch 36 (see FIG. 2). In contrast, since the switch 35 is turned off (see FIG. 2), the node N4 is electrically floated. Accordingly, since the inductor 33 is not subjected to the influence of the outermost turn of the wire 41 (floated), reduction of the inductance value can be suppressed.

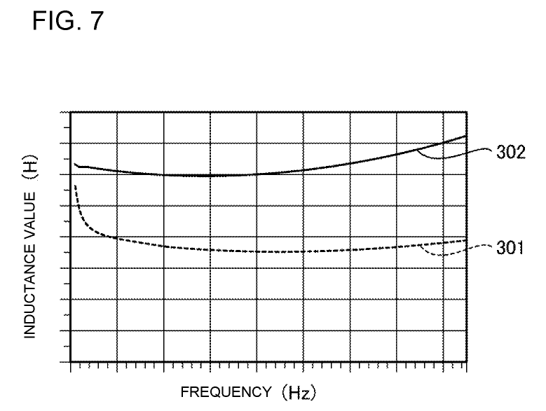

FIG. 7 illustrates a circuit simulation result of the inductor of the input matching circuit according to the first embodiment. In FIG. 7, the vertical axis represents the inductance value (henrys, H), and the horizontal axis represents the frequency (Hz).

Line 301 indicates the inductance value of the inductor 33 in the second operation mode in the case of the input matching circuit 111 according to the reference example (when the node N4 is fixedly connected to the reference potential).

Line 302 indicates the inductance value of the inductor 33 in the second operation mode in the case of the input matching circuit 11 according to the first embodiment (when the switch 35 between the node N4 and the reference potential is turned off).

As indicated by line 302, in the second operation mode, when the switch 35 between the node N4 and the reference potential is turned off, the input matching circuit 11 can suppress reduction of the inductance value of the inductor 33.

### Circuit Simulation Result of Power Amplification Circuit 1

A circuit simulation result of the power amplification circuit 1 according to the first embodiment and a power amplification circuit according to a comparative example is described.

The power amplification circuit 1 according to the first embodiment is as illustrated in FIG. 1. The input matching circuit 11 according to the first embodiment is as illustrated in FIG. 2.

In the power amplification circuit according to the comparative example, the input matching circuit 11 is replaced with an input matching circuit 211 below in the power amplification circuit 1.

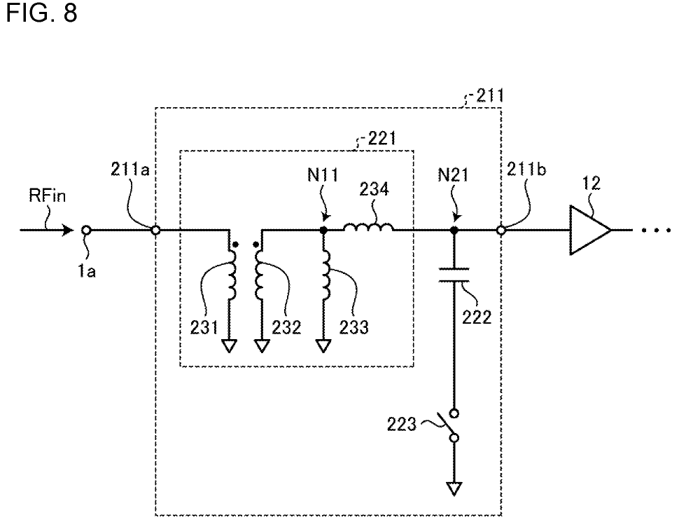

FIG. 8 illustrates a configuration of the input matching circuit according to the comparative example. A terminal 211a of the input matching circuit 211 is electrically connected to the terminal 1a. A terminal 211b of the input matching circuit 211 is electrically connected to the input terminal of the amplifier 12.

The input matching circuit 211 includes a transformer 221, a capacitor 222, and a switch 223.

The transformer 221 includes a first winding 231, a second winding 232, a third winding 233, and a fourth winding 234.

One end of the first winding 231 is electrically connected to the terminal 211a. Another end of the first winding 231 is electrically connected to the reference potential.

One end of the second winding 232 is electrically connected to a node N11. Another end of the second winding 232 is electrically connected to the reference potential.

The first winding 231 and the second winding 232 are coupled by a magnetic field.

One end of the third winding 233 is electrically connected to the node N11. Another end of the third winding 233 is electrically connected to the reference potential.

One end of the fourth winding 234 is electrically connected to the node N11. Another end of the fourth winding 234 is electrically connected to a node N21. The node N21 is electrically connected to the terminal 211b.

One end of the capacitor 222 is electrically connected to the node N21. Another end of the capacitor 222 is electrically connected to one end of the switch 223. Another end of the switch 223 is electrically connected to the reference potential.

In the first operation mode, the switch 223 is controlled to be turned on. In the second operation mode, the switch 223 is controlled to be turned off.

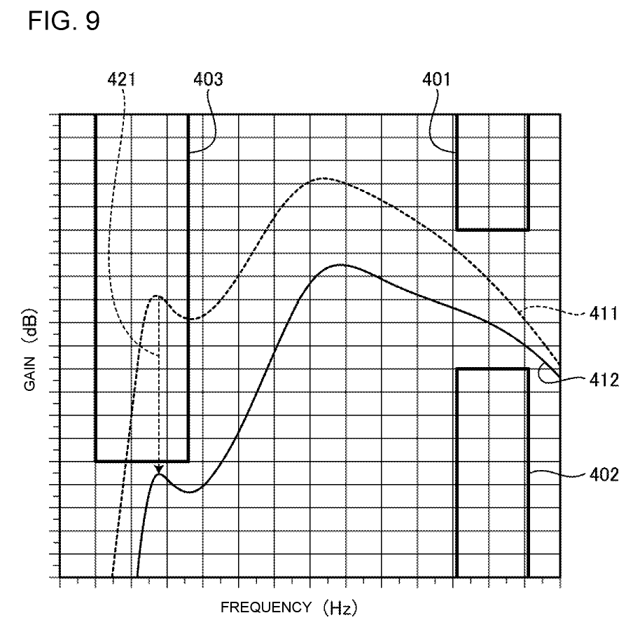

FIG. 9 illustrates a circuit simulation result of the power amplification circuits according to the first embodiment and according to the comparative example. Specifically, FIG. 9 illustrates the S-parameter (scattering parameter) transmission characteristics of the amplifier in the second operation mode of the power amplification circuits according to the first embodiment and according to the comparative example. In FIG. 9, the vertical axis represents the gain (dB), and the horizontal axis represents the frequency (Hz).

In FIG. 9, line 401 indicates an upper limit value, in specification, of the gain in the second band B. Line 402 indicates a lower limit value, in specification, of the gain in the second band B. Since the power amplification circuit is operated in the second operation mode, it is necessary that the waveform of the transmission characteristics of the amplifier pass between line 401 and line 402.

Line 403 indicates an upper limit value, in specification, of the gain in the first band A. Since the power amplification circuit is operated in the second operation mode, line 403 indicates an upper limit value, in specification, of the OOB gain. It is necessary that the waveform of the transmission characteristics of the amplifier pass below line 403.

Line 411 is a waveform indicating the transmission characteristics of the amplifier of the power amplification circuit according to the comparative example. The inductance values of the first winding 231 to the fourth winding 234 (see FIG. 7) and the electrostatic capacitance value of the capacitor 222 (see FIG. 7) are adjusted such that the gain in the second band B is between the upper limit value (line 401) and the lower limit value (line 402).

As a result, the gain in the first band A exceeds the upper limit value of the OOB gain (line 403). That is, with the power amplification circuit according to the comparative example, the OOB gain becomes a value equal to or greater than the reference.

Line 412 is a waveform indicating the transmission characteristics of the amplifier of the power amplification circuit 1 according to the first embodiment. The inductance values of the inductor 33 (see FIG. 2) and the electrostatic capacitance value of the capacitor 31 (see FIG. 2) are adjusted such that the gain in the second band B is between the upper limit value (line 401) and the lower limit value (line 402).

As a result, with the power amplification circuit 1 according to the first embodiment, unlike the case with the power amplification circuit according to the comparative example, the gain in the first band A becomes smaller than the upper limit value, in specification, of the OOB gain (line 403).

The reason for this is that, in the second operation mode, since the input matching circuit 11 becomes the high-pass filter (see FIG. 4), the input matching circuit 11 can suppress the radio-frequency signal of the first band A.

Compared to the power amplification circuit according to the comparative example, the power amplification circuit 1 according to the first embodiment can suppress the OOB gain in the second operation mode as indicated by arrow 421 and suppress the OOB gain in the second operation mode.

### Summarization

As has been described, the input matching circuit 11 can suppress the OOB gain in the second operation mode. Accordingly, the power amplification circuit 1 can suppress the OOB gain in the second operation mode.

### Second Embodiment

### Entire Configuration

The entirety configuration of a power amplification circuit according to a second embodiment is that, in the power amplification circuit according to the second embodiment, the input matching circuit 11 of the power amplification circuit 1 according to the first embodiment (see FIG. 1) is replaced with an input matching circuit 11A. Thus, illustration and description of the entire configuration of the power amplification circuit are omitted.

### Configuration of Input Matching Circuit 11A

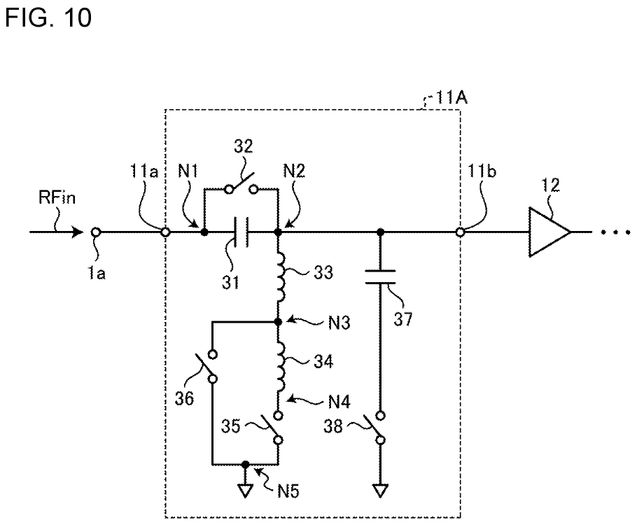

FIG. 10 illustrates a configuration of an input matching circuit according to the second embodiment. Compared to the input matching circuit 11 (see FIG. 2), the input matching circuit 11A further includes a capacitor 37 and a switch 38.

The capacitor 37 corresponds to an example of a "second capacitor" of the present disclosure. The switch 38 corresponds to an example of a "fourth switch" of the present disclosure.

One end of the capacitor 37 is electrically connected to the node N2. Another end of the capacitor 37 is electrically connected to one end of the switch 38. Another end of the switch 38 is electrically connected to the reference potential.

In the first operation mode, the switch 38 is controlled by the control circuit to be turned on. In the second operation mode, the switch 38 is controlled by the control circuit to be turned off.

### Equivalent Circuit of Input Matching Circuit 11A in First Operation Mode

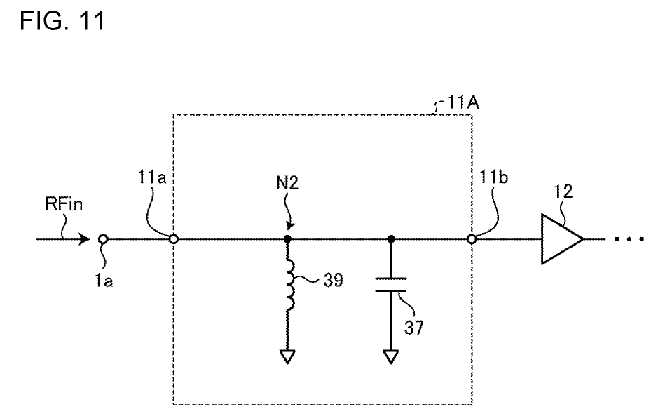

FIG. 11 is an equivalent circuit diagram of the input matching circuit according to the second embodiment. Specifically, FIG. 11 is the equivalent circuit diagram of the input matching circuit 11A in the first operation mode.

In the first operation mode, the switch 32 is controlled to be turned on, the switch 35 is controlled to be turned on, the switch 36 is controlled to be turned off, and the switch 38 is controlled to be turned on. Accordingly, the input matching circuit 11A is an LC parallel resonance circuit of the inductor 39 and the capacitor 37. Here, the inductor 33 and the inductor 34 are connected in series in the inductor 39.

### Equivalent Circuit of Input Matching Circuit 11A in Second Operation Mode

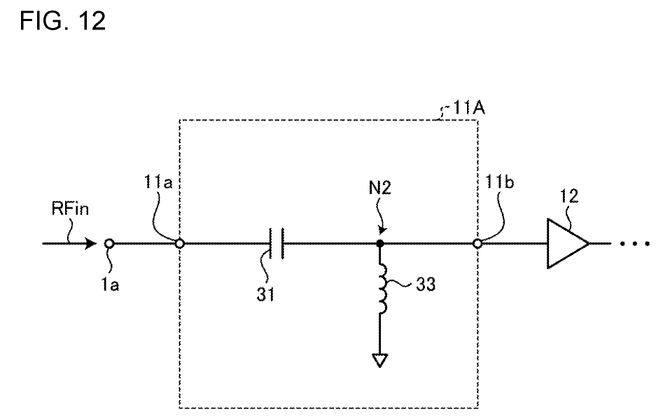

FIG. 12 is an equivalent circuit diagram of the input matching circuit according to the second embodiment. Specifically, FIG. 12 is the equivalent circuit diagram of the input matching circuit 11A in the second operation mode.

In the second operation mode, the switch 32 is controlled to be turned off, the switch 35 is controlled to be turned off, the switch 36 is controlled to be turned on, and the switch 38 is controlled to be turned off. Accordingly, the input matching circuit 11A becomes a high-pass filter including the capacitor 31 and the inductor 33 which are connected in an L shape.

### Effect

Compared to the input matching circuit 11, the input matching circuit 11A can reduce the size of the inductor 33 and the inductor 34.

The above-described embodiments are for ease of understanding of the present disclosure, but not for interpretation of the present disclosure by limiting the present disclosure. The present disclosure can be changed/modified without departing from the gist thereof, and the present disclosure includes equivalents thereof.

What is claimed is:

1. A matching circuit comprising:
a first capacitor having a first end electrically connected to a first node and a second end electrically connected to a second node;
a first switch having a first end electrically connected to the first node and a second end electrically connected to the second node;
a first inductor having a first end electrically connected to the second node and a second end electrically connected to a third node;
a second inductor having a first end electrically connected to the third node and a second end electrically connected to a fourth node;
a second switch having a first end electrically connected to the fourth node and a second end electrically connected to a reference potential; and
a third switch having a first end electrically connected to the third node and a second end electrically connected to the reference potential.

2. The matching circuit according to claim 1, further comprising:
a second capacitor having a first end electrically connected to the second node; and
a fourth switch having a first end electrically connected to a second end of the second capacitor, and a second end electrically connected to the reference potential.

3. The matching circuit according to claim 1, wherein the first inductor and the second inductor comprise a single wire wound in a spiral manner.

4. The matching circuit according to claim 2, wherein the first inductor and the second inductor comprise a single wire wound in a spiral manner.

5. The matching circuit according to claim 2, wherein the matching circuit has:
a first operation mode in which the first switch is turned on, the second switch is turned on, the third switch is turned off, and the fourth switch is turned on; and
a second operation mode in which the first switch is turned off, the second switch is turned off, the third switch is turned on, and the fourth switch is turned off.

6. A power amplification circuit comprising:
the matching circuit according to claim 2;
a first amplifier having an input terminal electrically connected to the second node;
an interstage matching circuit having a first end electrically connected to an output terminal of the first amplifier;
a fifth switch having a first end electrically connected to a second end of the interstage matching circuit;
a sixth switch having a first end electrically connected to the second end of the interstage matching circuit;
a second amplifier having an input terminal electrically connected to a second end of the fifth switch; and
a third amplifier having an input terminal electrically connected to a second end of the sixth switch.

7. The power amplification circuit according to claim 6, wherein the power amplification circuit has:
a first operation mode in which the first switch is turned on, the second switch is turned on, the third switch is turned off, the fourth switch is turned on, the fifth switch is turned on, and the sixth switch is turned off; and
a second operation mode in which the first switch is turned off, the second switch is turned off, the third
switch is turned on, the fourth switch is turned off, the fifth switch is turned off, and the sixth switch is turned on.
